(19) United States
(12) Patent Application Publication
(10) Pub. No.: US 2007/0024766 A1
(43) Pub. Date: Feb. 1, 2007

(54) Organic thin film transistor display panel

(75) Inventors: Keun-Kyu Song, Yongin-si (KR); Yong-Uk Lee, Seongnam-si (KR)

Correspondence Address: MACPHERSON KWOK CHEN & HEID LLP, 2033 GATEWAY PLACE, SUITE 400, SAN JOSE, CA, 95110, US

(73) Assignee: Samsung Electronics Co., Ltd.

(21) Appl. No.: 11/495,835

(22) Filed: Jul. 28, 2006

(30) Foreign Application Priority Data
Jul. 29, 2005 (KR) 10-2005-0069351

(51) Int. Cl. G02F 1/136

(52) U.S. Cl. 349/42

(57) ABSTRACT

An organic thin film transistor array panel according to an embodiment of the present invention includes forming a gate line on an insulating plastic or glass substrate; forming a gate insulating layer on the gate line; forming a data line and a drain electrode on the gate insulating layer, the data line and the drain electrode comprising a first conductive film and a second conductive film of indium tin oxide (ITO) or indium zinc oxide (IZO) that has a work function similar to that of the organic semiconductor that is deposited overlapping the data line and the drain electrode; forming a passivation layer on the organic semiconductor; and forming a pixel electrode connected to the drain electrode on the passivation and the gate insulating layer.

### CROSS-REFERENCE TO RELATED APPLICATION

This Application claims priority from Korean patent application number 10-2005-0069351 filed on Jul. 29, 2005, and all the benefits accruing therefrom under 35 U.S.C. §119, the contents of which are incorporated by reference herein.

### FIELD OF THE INVENTION

The present invention relates to an organic thin film transistor array panel and a manufacturing method thereof.

### DESCRIPTION OF RELATED ART

Organic thin film transistors (OTFT) employ an organic active layer instead of inorganic semiconductor such as silicon. Since an organic semiconductor can be easily deposited at a low temperature by a solution process, etc., it is more suitable for large flat panel displays than inorganic semiconductor that use chemical vapor deposition. In addition, since organic material can be easily formed of fiber or film, OTFTs can be used with flexible display devices.

However, the manufacturing process for an organic semiconductor is more sensitive to process conditions than for inorganic semiconductors. Moreover, organic semiconductor may generate a Schottky barrier between the low resistivity material conventionally used for contacts at the source/drain electrode metal which alter the characteristics of the OTFT.

Accordingly, conventional OTFT array panels may have complicated layered structures and need additional process steps for reducing the degradation of OTFTs.

### SUMMARY OF THE INVENTION

In accordance with the principles of the invention, the difference in work function between an organic semiconductor layer deposited on a source or a drain electrode is taken into account to avoid generation of a Schottky barrier so that the injection and transport of charge carriers is not obstructed. An organic thin film transistor array panel according to an embodiment of the present invention includes forming a gate line on an insulating plastic or glass substrate; forming a gate insulating layer on the gate line; forming a data line and a drain electrode on the gate insulating layer, the data line and the drain electrode comprising a first conductive film and a second conductive film of indium tin oxide (ITO) or indium zinc oxide (IZO) that has a work function similar to that of the organic semiconductor that is deposited overlapping the data line and the drain electrode; forming a passivation layer on the organic semiconductor; and forming a pixel electrode connected to the drain electrode on the passivation and the gate insulating layer. The gate electrode, source electrode, and drain electrode along with an organic semiconductor island form an organic TFT having a channel formed in the organic semiconductor island disposed between the source electrode and the drain electrode.

The formation of the passivation layer may include: forming a first passivation layer comprising organic material; and forming a second passivation layer comprising ITO or IZO on the first passivation layer. The organic semiconductor and the first passivation layer may be formed by a solution process advantageously performed at a temperature of about 25° C. to about 130° C.

The formation of the organic semiconductor and the formation of the passivation may include: depositing an organic semiconductor layer, a first passivation film, and a second passivation film in sequence; etching the second passivation film to form the second passivation layer; and etching the first passivation film and the organic semiconductor layer by using the second passivation layer as an etch mask to form the first passivation layer and the organic semiconductor. The first passivation layer and the organic semiconductor may be dry etched.

### BRIEF DESCRIPTION OF THE DRAWINGS

The present invention will become more apparent from the ensuing description when read together with the drawing, in which:

FIG. 1 is a layout view of a TFT array panel for a liquid crystal display according to an embodiment of the present invention;

FIG. 2 is a sectional view of the TFT array panel shown in FIG. 1 taken along the line II-II;

FIGS. 3, 5 and 7 are layout view of the organic TFT array panel shown in FIGS. 1 and 2 in intermediate steps of a manufacturing method thereof according to an embodiment of the present invention;

FIG. 4 is a sectional view of the organic TFT array panel shown in FIG. 3 taken along line IV-IV;

FIG. 6 is a sectional view of the organic TFT array panel shown in FIG. 5 taken along line VI-VI; and

FIG. 8 is a sectional view of the organic TFT array panel shown in FIG. 7 taken along line VIII-VIII.

### DETAILED DESCRIPTION OF EMBODIMENTS

In the drawings, the thickness of layers and regions are exaggerated for clarity. Like numerals refer to like elements throughout. It will be understood that when an element such as a layer, region or substrate is referred to as being “on” another element, it can be directly on the other element or intervening elements may also be present. In contrast, when an element is referred to as being “directly on” another element, there are no intervening elements present.

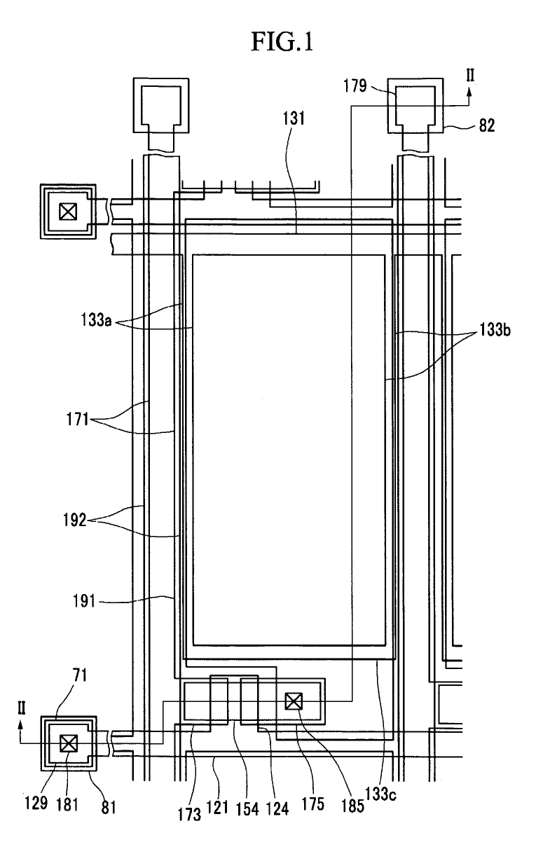

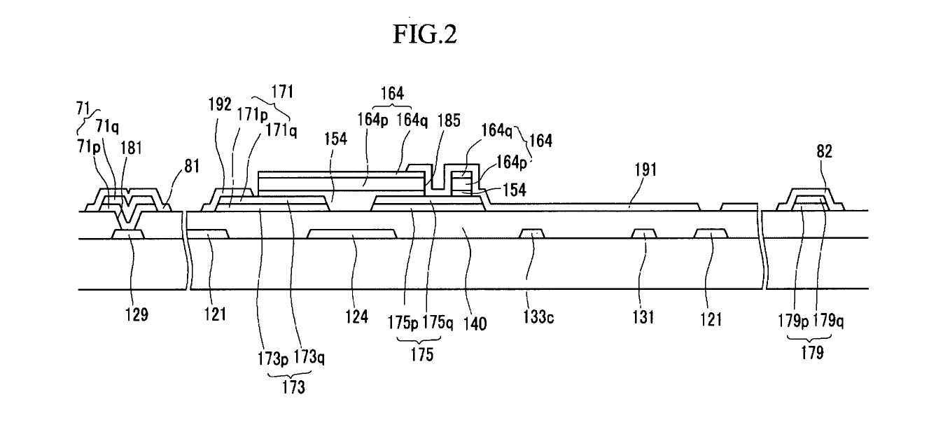

FIG. 1 is a layout view of a TFT array panel for a liquid crystal display according to an embodiment of the present invention, and FIG. 2 is a sectional view of the TFT array panel shown in FIG. 1 taken along the line II-II. A plurality of gate lines 121 and a plurality of storage electrode lines 131 are formed on an insulating substrate 110 such as transparent glass or plastic.

Gate lines 121 transmit gate signals and extend substantially in a transverse direction. Each of gate lines 121 includes a plurality of gate electrodes 124 projecting upward and an end portion 129 having a large area for contact with another layer or an external driving circuit. A gate driving circuit (not shown) for generating the gate signals may be mounted on a flexible printed circuit (FPC) film (not shown), which may be attached to the substrate 110, directly mounted on the substrate 110, or integrated onto the substrate 110. Gate lines 121 may extend to be connected to a driving circuit that may be integrated on the substrate 110.

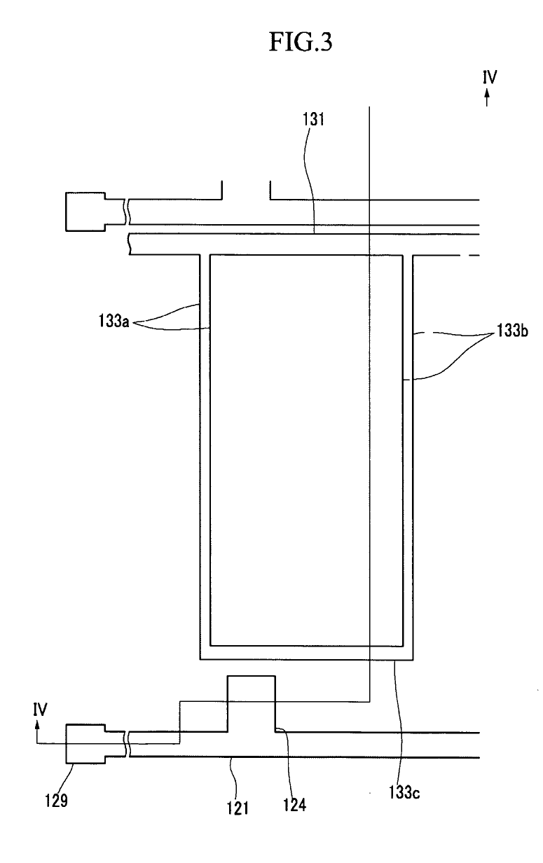

Storage electrode lines 131 are supplied with a predetermined voltage and each of storage electrode lines 131 includes a stem extending substantially parallel to gate lines 121 and a plurality of rectangular storage electrodes 133a, 133b and 133c branched from the stem. Each of storage electrode lines 131 is disposed between two adjacent gate lines 121 and the stem is close to upper one of the two adjacent gate lines 121. As shown in FIG. 3, each of the storage electrodes includes two longitudinal portions 133a and 133b connected to the stem and a transverse portion 133c connected to the ends of the longitudinal portions. However, storage electrode lines 131 may have various shapes and arrangements.

Gate lines 121 and storage electrode lines 131 may be preferably made of Al containing metal such as Al and Al alloy, Ag containing metal such as Ag and Ag alloy, Cu containing metal such as Cu and Cu alloy, Mo containing metal such as Mo and Mo alloy, Cr, Ta, or Ti. However, they may have a multi-layered structure including two conductive films (not shown) having different physical characteristics. One of the two films may be made of low resistivity metal including Al containing metal, Ag containing metal, and Cu containing metal for reducing signal delay or voltage drop. The other film may be made of material such as Mo containing metal, Cr, Ta, or Ti, which has good physical, chemical, and electrical contact characteristics with other materials such as indium tin oxide (ITO) or indium zinc oxide (IZO). Good examples of the combination of the two films are a lower Cr film and an upper Al (alloy) film and a lower Al (alloy) film and an upper Mo (alloy) film. However, gate lines 121 and storage electrode lines 131 may be made of various metals or conductors.

The lateral sides of gate lines 121 and storage electrode lines 131 are inclined relative to a surface of the substrate 110, and the inclination angle thereof ranges about 30-80 degrees.

Agate insulating layer 140 is formed on gate lines 121 and storage electrode lines 131. The gate insulating layer 140 may be made of silicon oxide that may have a surface treated with octadecyl-trichloro-silane (OTS). However, the gate insulating layer 140 may be made of an inorganic insulator such as silicon nitride, or an organic insulator such as maleimide-styrene, polyvinylphenol (PVP), and modified cyanoethyl pullulan (m-CEP). Gate insulating layer 140 has a plurality of contact holes 181 exposing the end portions 129 of gate lines 121.

A plurality of data lines 171, a plurality of drain electrodes 175, and a plurality of intermediate layers 71 are formed on the gate insulating layer 140. Data lines 171 transmit data signals and extend substantially in the longitudinal direction to intersect gate lines 121. Each of data lines 171 also intersects storage electrode lines 131 and runs between adjacent storage electrodes 133a, 133b and 133c. Each data line 171 includes a plurality of source electrodes 173 projecting toward the gate electrodes 124 and an end portion 179 having a large area for contact with another layer or an external driving circuit. A data driving circuit (not shown) for generating the data signals may be mounted on a FPC film (not shown), which may be attached to the substrate 110, directly mounted on the substrate 110, or integrated onto the substrate 110. Data lines 171 extend to be connected to a driving circuit that may be integrated on the substrate 110.

The drain electrodes 175 are separated from data lines 171 and disposed opposite source electrodes 173 with respect to gate electrodes 124. Intermediate layers 71 are connected to the end portions 129 of the gate lines 129 through contact holes 181 and fully cover exposed portions of end portions 129.

Data lines 171, drain electrodes 175, and intermediate layers 71 include two conductive films, a lower film 171p, 175p and 71p and an upper film 171q, 175q and 71q disposed thereon, which have different physical characteristics.

The lower film 171p, 175p and 71p may be made of low resistivity metal including Al containing metal, Ag containing metal, Cu containing metal such as Cu and Cu alloy, Mo containing metal, and Cr containing metal, for reducing signal delay or voltage drop. The upper film 171q, 175q and 71q may be made of material selected in consideration of the characteristics of the organic semiconductor, as follows.

The difference in the work function between an organic semiconductor and the material for the upper film 171q, 175q and 71q may be so small that charge carriers can be effectively injected into the organic semiconductor from a source electrode 173 or a drain electrode 175. When the difference in the work function therebetween is large, a Schottky barrier generated between the organic semiconductor and the upper film 171q, 175q and 71q may obstruct the injection and the transport of the charge carriers.

Examples of such a material for the upper film 171q, 175q and 71q include ITO and IZO. ITO and IZO has a work function equal to about 4.5-5.0 eV, which is slightly different from an organic semiconductor having a work function equal to about 5.0-5.5 eV. Therefore, ITO and IZO can form an ohmic contact with the organic semiconductor to effectively inject charge carriers into the organic semiconductor. In addition, ITO and IZO have good adhesion with the organic semiconductor.

Since data line 171 and source electrode 173 and drain electrode 175 are disposed on the same layer, the number of the process steps and the masks for manufacturing the organic TFT array panel can be reduced.

In FIG. 2, the lower and upper films of source electrodes 173 and end portions 179 are denoted by additional characters p and q, respectively. A plurality of organic semiconductor islands 154 are formed on source electrodes 173, drain electrodes 175, and gate insulating layer 140. Organic semiconductor islands 154 may be formed by deposition including spin coating and by lithography with or without etch. However, organic semiconductor islands 154 may include a high molecular compound or a low molecular compound, which is soluble in an aqueous solution or organic solvent. In this case, organic semiconductor islands 154 can be formed by (inkjet) printing and a partition (not shown) for confining organic semiconductor islands 154 may be required.

Organic semiconductor islands 154 may be made of, or from derivatives of, tetracene or pentacene with substituent. Alternatively, organic semiconductor islands 154 may be made of oligothiophene including four to eight thiophenes connected at the positions 2, 5 of thiophene rings.

Organic semiconductor islands 154 may be made of perylenetetracarboxylic dianhydride (PTCDA), naphthalenetetracarboxylic dianhydride (NTCDA), or their imide derivatives. Alternatively, organic semiconductor islands 154 may be made of metallized phthalocyanine or halogenated derivatives thereof. The metallized phthalocyanine may include Cu, Co, Zn, etc. Organic semiconductor islands 154 may also be made of perylene, coronene or derivatives thereof with a substituent.

A gate electrode 124, a source electrode 173, and a drain electrode 175 along with an organic semiconductor island 154 form an organic TFT having a channel formed in the organic semiconductor island 154 disposed between the source electrode 173 and the drain electrode 175.

A plurality of passivation islands 164 are formed on organic semiconductor islands 154. Each of the passivation islands 164 has substantially the same planar shape as the underlying organic semiconductor island 154 and includes a lower passivation layer 164p and an upper passivation layer 164q.

The lower passivation layer 164p may be made of organic insulating material that can be deposited at a low temperature. An example of such a material such as fluorine based polymer or parylene that can be formed at room temperature or a low temperature. The lower passivation layer 164p protects organic semiconductor islands 154 from being damaged in the manufacturing process.

The upper passivation layer 164q may be made of ITO or IZO that can be formed at a low temperature lower than about 130° C. to reduce the effect of the forming step thereof on the organic semiconductor island 154. The upper passivation layer 164q serves as an etch mask for forming the lower passivation layer 164p having weak compatibility with a photoresist.

Each pair of a passivation island 164 and a semiconductor island 154 has a contact hole exposing a drain electrode 175 disposed thereon.

A plurality of pixel electrodes 191, a plurality of subsidiary data lines 192, and a plurality of contact assistants 81 and 82 are formed on the passivation islands 164, exposed portions of the gate insulating layer 140 and data lines 171, and the intermediate layers 71. They may be made of transparent conductor such as ITO or IZO or reflective conductor such as Ag, Al, Cr, or alloys thereof.

The pixel electrodes 191 are physically and electrically connected to the drain electrodes 175 through the contact holes 185 such that the pixel electrodes 191 receive data voltages from the drain electrodes 175. The pixel electrodes 191 supplied with the data voltages generate electric fields in cooperation with a common electrode (not shown) of an opposing display panel (not shown) supplied with a common voltage, which determine the orientations of liquid crystal molecules (not shown) of a liquid crystal layer (not shown) disposed between the two electrodes. According to another embodiment, a pixel electrode 191 and the common electrode flow a current in a light emitting layer (not shown) to emit light.

A pixel electrode 191 overlaps a storage electrode line 131 including storage electrodes 133a, 133b and 133c to form a capacitor.

The subsidiary data lines 192 extend along data lines 171 and overlap data lines 171. The subsidiary data lines 192 is wider than data lines 171 to fully cover most portions of data lines 171 except for source electrodes 173. However, the width of the subsidiary data lines 192 may be smaller than that of data lines 171. It is preferable that the distance between the subsidiary data lines 192 and the pixel electrodes 191 is small for increasing the aperture ratio.

The subsidiary data lines 171 protect data lines 171 and prevent data lines 171 from contacting an overlying layer such as a liquid crystal layer (not shown), etc.

The contact assistants 81 cover and contact the intermediate layers 71 and are electrically connected to the end portions 129 of gate lines 121. The contact assistants 82 cover, contact, and are connected to the end portions 179 of data lines 171. The contact assistants 81 and 82 protect the end portions 129 and 179 and enhance the adhesion between the end portions 129 and 179 and external devices. A protection layer (not shown) may be formed on the pixel electrodes 191 and the subsidiary data lines 192.

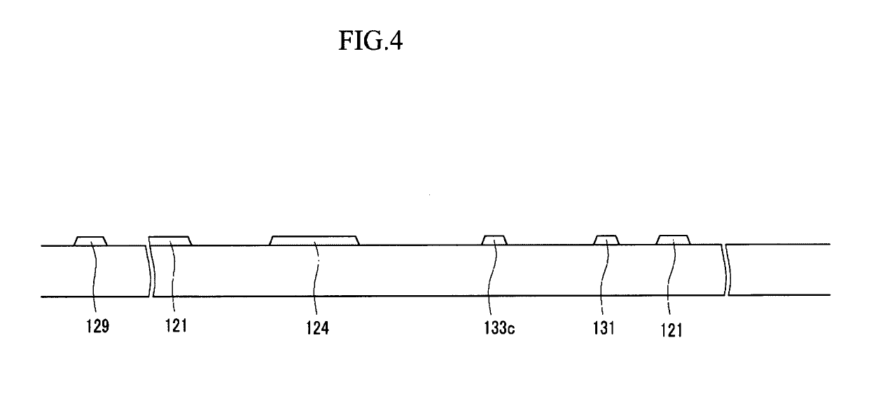

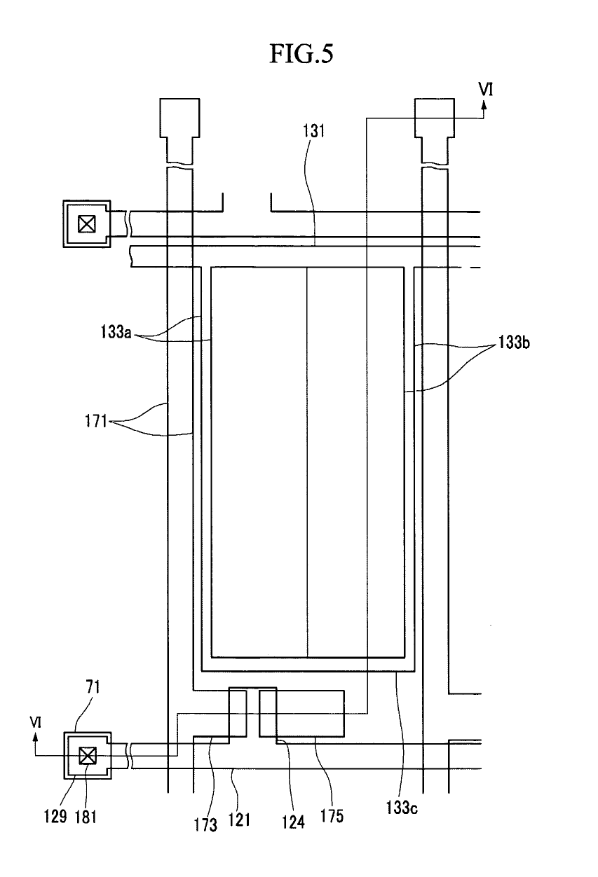

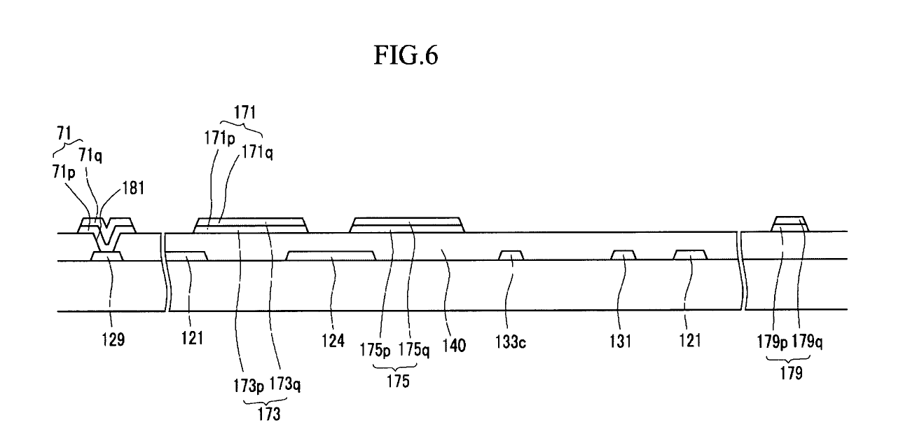

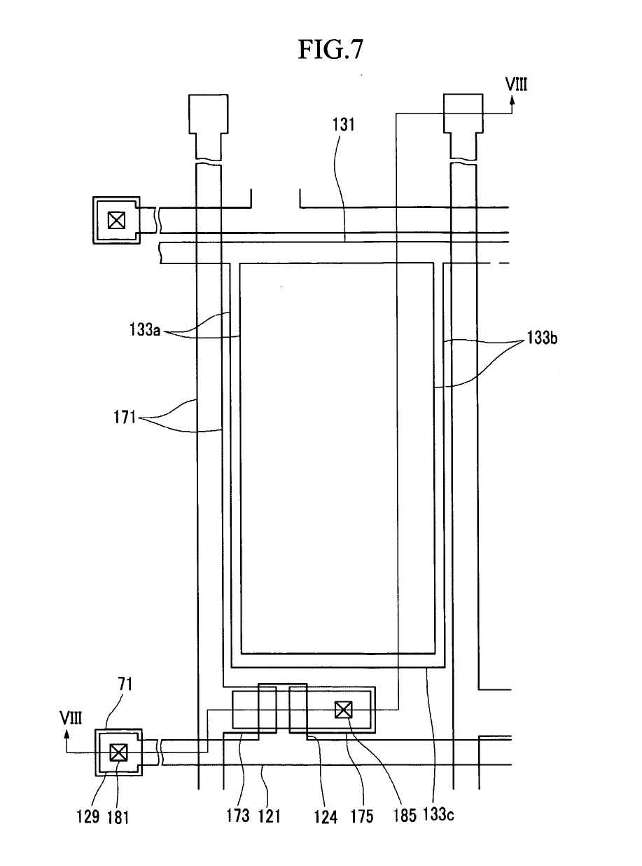

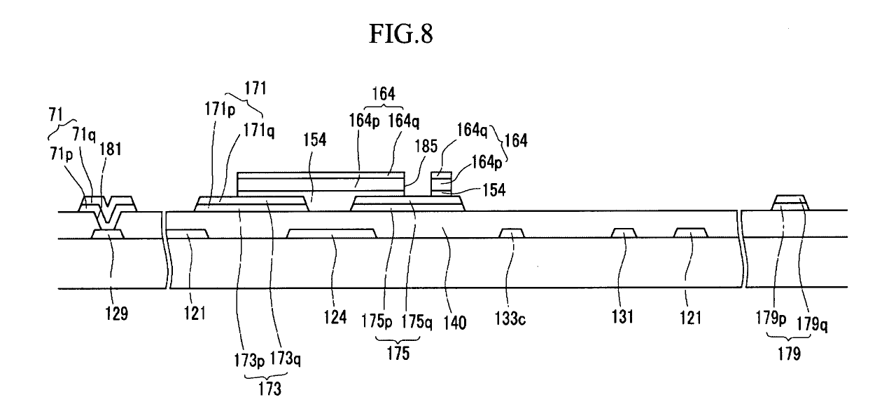

Now, a method of manufacturing the TFT array panel shown in FIGS. 1 and 2 according to an embodiment of the present invention will be described in detail with reference to FIGS. 3, 4, 5, 6, 7 and 8 as well as FIGS. 1 and 2. FIGS. 3, 5 and 7 are layout view of the organic TFT array panel shown in FIGS. 1 and 2 in intermediate steps of a manufacturing method thereof according to an embodiment of the present invention, FIG. 4 is a sectional view of the organic TFT array panel shown in FIG. 3 taken along line IV-IV, FIG. 6 is a sectional view of the organic TFT array panel shown in FIG. 5 taken along line VI-VI, and FIG. 8 is a sectional view of the organic TFT array panel shown in FIG. 7 taken along line VIII-VIII.

Referring to FIGS. 3 and 4, a plurality of gate lines 121 including gate electrodes 124 and end portions 129 and a plurality of storage electrode lines 131 including storage electrodes 133a, 133b and 133c are formed on an insulating substrate 110 such as transparent glass or plastic.

Referring to FIGS. 5 and 6, a gate insulating layer 140 is spin coated on gate lines 121 and storage electrode lines 131, and subjected to light-exposure and development to form a plurality of contact holes 181 exposing the end portions 129 of gate lines 121.

Subsequently, a lower film of Mo alloy and an upper film of ITO are sequentially sputtered on the gate insulating layer 140, and etched using a single etchant to form a plurality of data lines 171 including source electrodes 173 and end portions, a plurality of drain electrodes 175, and a plurality of intermediate layers 71. In the figures, the lower and upper films of data lines 171, source electrodes 173, the drain electrodes 175, the end portions 179, and the intermediate layers 71 are denoted by additional characters p and q, respectively.

An organic semiconductor layer preferably made of pentacene is spin coated on data lines 171, the drain electrodes 175, the intermediate layers 71, and the gate insulating layer 140. A lower passivation film preferably including parylene is spin coated at a low temperature. The lower passivation film protects the organic semiconductor layer.

Next, an upper passivation film preferably including ITO or IZO is sputtered on the lower passivation film at a temperature lower than about 130° C., for example from a room temperature of about 25° C. to a temperature of about 130° C. such that the organic semiconductor layer may not be affected by the deposition of the upper passivation film.

Referring to FIGS. 7 and 8, the upper passivation film is subjected to photolithography and etch to form a plurality of upper layers 164q of passivation islands 164q, and then the lower passivation film and the organic semiconductor film are dry etched in sequence by using the upper passivation layers 164q as an etch mask to form a plurality of lower passivation layers 164p and a plurality of organic semiconductor islands 154. At this time, a plurality of contact holes 185 exposing the drain electrodes 175 are formed at and organic semiconductor islands 154 and passivation islands 164 including the upper passivation layers 164q and the lower passivation layers 164p.

Since the upper passivation layers 164q that can be processed at a low temperature serve as a mask for patterning the organic semiconductor layer, the chemical attack into organic semiconductor islands 154 can be prevented.

Finally, a plurality of pixel electrodes 191, a plurality of subsidiary data lines 192, and a plurality of contact assistants 81 and 82 are formed. The pixel electrodes 191, the subsidiary data lines 192, and the contact assistants 81 and 82 may be made of ITO or IZO that can be formed at a low temperature and etched by weak basic etchant not to affect organic semiconductor islands 154.

Upper passivation layers 164q and the upper film 171q, 175q and 71q of data lines 171, the drain electrodes 175, and the intermediate layers 71 may be made of materials having etch selectivity with the material of the pixel electrodes 191, the contact assistants 81 and 82, and the subsidiary data lines 191. Then, the upper passivation layers 164q and the upper film 171q, 175q and 71q may not be etched when the pixel electrodes 191, etc., are formed. In addition, the upper passivation layers 164q and the upper film 171q, 175q and 71q may have etch selectivity. For example, the upper film 171q, 175q and 71q, the upper passivation layers 164q, and the pixel electrodes 191 may be made of (poly)crystalline ITO, IZO, and amorphous ITO.

However, the upper passivation layers 164q, the upper film 171q, 175q and 71q, and the pixel electrodes 191 may have no etch selectivity, and in this case, portions of the upper passivation layers 164q and the upper film 171q, 175q and 71q may be removed during the etch of the pixel electrodes 191, etc.

Since the data lines, the source electrodes, and the drain electrodes can be formed from a single layer, the number of the process steps and the masks may be reduced with maintaining the low resistance of the data lines and the characteristics of the organic TFTs. The present invention can be employed to any display devices including LCD and OLED display.

Although preferred embodiments of the present invention have been described it will be apparent to those skilled in the art that modifications of the basic inventive concepts herein taught may be made without, however, departing from the spirit and scope of the invention.

What is claimed is:

1. An organic thin film transistor array panel comprising:
a gate line formed on a substrate;
a gate insulating layer formed on the gate line;
a data line and a drain electrode formed on the gate insulating layer; and
an organic semiconductor formed on the data line and the drain electrode, said data line and said drain electrode having formed thereon at least one conductive film comprising ITO or IZO.

2. An organic thin film transistor array panel of claim 1 further comprising a conductivity film adhering over said data line and said drain electrode and beneath said one conductive film.

3. An organic thin film transistor array panel of claim 2 wherein said conductivity film comprises a metal having a resistivity lower than said one conductive film.

4. An organic thin film transistor array panel of claim 3 further comprising:
a passivation formed on the organic semiconductor; and
a pixel electrode connected to the drain electrode.

5. The organic thin film transistor array panel of claim 1, wherein the conductive film comprises at least one of Mo, Mo alloy, Cr, Cr alloy, Al, Al alloy, Cu, Cu alloy, Al, and Al alloy.

6. The organic thin film transistor array panel of claim 4, wherein the passivation comprises a first passivation layer and a second passivation layer comprising different materials.

7. The organic thin film transistor array panel of claim 6, wherein the first passivation layer comprises organic material.

8. The organic thin film transistor array panel of claim 6, wherein the first passivation layer comprises a fluorine based polymer or parylene.

9. The organic thin film transistor array panel of claim 6, wherein the second passivation layer comprises ITO or IZO.

10. The organic thin film transistor array panel of claim 6, wherein the organic semiconductor, the first passivation layer, and the second passivation layer have substantially the same planar shape.

11. The organic thin film transistor array panel of claim 6, wherein the organic semiconductor, the first passivation layer, and the second passivation layer have a contact hole, and the pixel electrode and the drain electrode are connected to each other through the contact hole.

12. The organic thin film transistor array panel of claim 4, further comprising a subsidiary data line covering the data line.

13. The organic thin film transistor array panel of claim 12, wherein the subsidiary data line and the pixel electrode comprise the same material.

14. The organic thin film transistor array panel of claim 4, further comprising a protection film disposed on the pixel electrode.

15. A method of manufacturing an organic thin film transistor array panel, the method comprising:
forming a gate line on the substrate;
forming a gate insulating layer on the gate line;
forming a data line and a drain electrode on the gate insulating layer, the data line and the drain electrode comprising a first conductive film and a second conductive film of ITO or IZO;
forming an organic semiconductor overlapping the data line and the drain electrode;
forming a passivation on the organic semiconductor; and
forming a pixel electrode connected to the drain electrode on the passivation and the gate insulating layer.

16. The method of claim 15, wherein the formation of the passivation comprises:
forming a first passivation layer comprising organic material; and
forming a second passivation layer comprising ITO or IZO on the first passivation layer.

17. The method of claim 16, wherein the organic semiconductor and the first passivation layer are formed by a solution process.

18. The method of claim 16, wherein the formation of the second passivation layer is performed at a temperature of about 25° C. to about 130° C.

19. The method of claim 16, wherein the formation of the organic semiconductor and the formation of the passivation comprise:
depositing an organic semiconductor layer, a first passivation film, and a second passivation film in sequence;
etching the second passivation film to form the second passivation layer; and
etching the first passivation film and the organic semiconductor layer by using the second passivation layer as an etch mask to form the first passivation layer and the organic semiconductor.

20. The method of claim 19, wherein the first passivation layer and the organic semiconductor are dry etched.

21. The method of claim 16, wherein both the first conductive film and the second conductive film are etched by using an etchant.

22. The method of claim 16, further comprising:
forming a protection layer after the pixel electrode is formed.

23. An organic thin film transistor array panel comprising:
a gate line formed on a substrate;
a gate insulating layer formed on the gate line;
a data line and a drain electrode formed on the gate insulating layer; and
an organic semiconductor formed on the data line and the drain electrode, said data line and said drain electrode having formed thereon at least one conductive film which takes into account the work function of said organic semiconductor to avoid obstruction of carrier injection thereto.
